(19) United States
(12) Patent Application Publication
(10) Pub. No.: US 2008/0302405 A1
(43) Pub. Date: Dec. 11, 2008

(54) Supplemental solar energy collector

(76) Inventor: Michael Intrieri, Northborough, MA (US)

Correspondence Address: Iandiorio Teska & Coleman, 260 Bear Hill Road, Waltham, MA, 02451-1018, US

(21) Appl. No.: 12/150,888

(22) Filed: Apr. 30, 2008

Related U.S. Application Data
(60) Provisional application No. 60/933,477, filed on Jun. 5, 2007.

(51) Int. Cl. H01L 31/052; H01L 31/048

(52) U.S. Cl. 136/246; 136/251

(57) ABSTRACT

A supplemental solar energy collection system. A photovoltaic panel converts incident radiation into electricity. A housing includes a top thermally conductive surface mated with the photovoltaic panel and serving as a thermal collector. Open channels behind the thermally conductive surface carry fluid in contact with the top thermally conductive surface for removing heat from the photovoltaic panel.

### RELATED APPLICATIONS

The subject invention claims the benefit of and priority to U.S. Provisional Application No. 60/933,477, filed Jun. 5, 2007 which is incorporated herein by reference.

### FIELD OF THE INVENTION

This subject invention relates to solar panels.

### BACKGROUND OF THE INVENTION

Solar panels serve to either heat a fluid or to convert solar radiation into electricity (e.g., photovoltaic panels). U.S. Pat. No. 6,080,927, incorporated herein by this reference, discloses a solar concentrator which both generates electricity and heats water flowing in pipes adjacent a solar cell array.

The known prior art regarding such hybrid systems, however, involves rather complex specialized designs which cannot be used in conjunction with commercially available photovoltaic panels. The prior art also fails to maximize the surface area of the heat transfer fluid contacting the photovoltaic panel. Moreover, the prior art typically involves complex and expensive designs.

Early hybrid systems focused on the individual photovoltaic cell. U.S. Pat. No. 4,002,031, incorporated herein by this reference, discloses a design which seeks to maximize the efficiency of the photovoltaic cell. U.S. Pat. No. 4,080,221, also incorporated herein by this reference, discloses a hybrid collector that allows electric energy in addition to thermal energy to be collected by air and liquid. The design is complex and difficult to manufacture. U.S. Pat. Nos. 6,029,656; 6,080,927; 4,095,997; 4,392,008; and 6,630,622, all incorporated herein by this reference, also disclose some form of a hybrid system.

### BRIEF SUMMARY OF THE INVENTION

It is therefore an object of this invention to provide a supplemental solar energy collection system which can be used in connection with commercially available photovoltaic panels.

It is a further object of this invention to provide such a system which is designed to maximize the surface area of the heat transfer fluid contacting the photovoltaic panel.

It is a further object of this invention to provide such a system which does not involve complex or expensive designs.

It is a further object of this invention to provide such a system which cools the photovoltaic panel to improve electrical efficiency.

It is a further object of this invention to provide such a system which maximizes efficiency and versatility while minimizing costs.

The subject invention results from the realization that a hermetically sealed housing can be inexpensively made out of a high thermally conductive material to mate with the rear of a photovoltaic panel to act as a thermal collector, heat exchanger, and conduit for liquid transport.

The subject invention, however, in other embodiments, need not achieve all these objectives and the claims hereof should not be limited to structures or methods capable of achieving these objectives.

This subject invention features a supplemental solar energy collection system comprising a photovoltaic panel for converting incident radiation into electricity and a housing with a top thermally conductive surface mated with the photovoltaic panel and serving as a thermal collector. Open channels behind the thermally conductive surface carry fluid in contact with the top thermally conductive surface for removing heat from the photovoltaic panel.

The preferred top thermally conductive surface is made of aluminum or another thermally conductive material. Thermal grease may be used between the top thermally conductive surface and the photovoltaic panel. Typically there is an inlet into the housing and at least one outlet out of the housing for fluid in the channels. In one embodiment, the housing includes a bottom surface and first and second side walls and first and second end walls connecting the bottom surface to the top surface. The channels may be defined by gaskets between the bottom surface and the top surface.

In one example, alternating plates extend from the first end wall to a location spaced from the second end wall and then from the second end wall to a location spaced from the second end wall and then from the second end wall to a location spaced from the first end wall. In another example, alternating plates extend from the first side wall to a location spaced from the second side wall and then from the second side wall to a location spaced from the first side wall. If the photovoltaic panel includes a frame, the housing may reside within the frame and insulation fills the frame over the housing.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a highly schematic exploded view showing the primary components associated with an example of a supplemental solar energy collection system in accordance with the subject invention;

FIG. 2 is a schematic bottom view of the housing portion of the system shown in FIG. 1;

FIG. 3 is a schematic view showing the top and side portions of the housing shown in FIG. 2;

FIG. 4 is a schematic three-dimensional rear view showing the housing of FIGS. 2 and 3 assembled onto a photovoltaic panel;

FIG. 5 is a schematic three-dimensional top view showing a complete system in accordance with the subject invention installed on the roof of a dwelling;

FIG. 6 is a schematic partially cut away view showing the bottom portion of the supplemental energy collector housing in accordance with the subject invention;

FIG. 7 is a schematic three-dimensional top view showing an example of a hermetically sealed housing in accordance with the subject invention;

FIG. 8 is another schematic top view of a hermetically sealed housing in accordance with the subject invention;

FIG. 9 is another schematic view of the bottom of a hermetically sealed housing in accordance with the subject invention;

FIG. 10 is a schematic view showing the front side wall of a hermetically sealed housing in accordance with the subject invention;

FIG. 11 is a schematic three-dimensional view showing a hermetically housing mated to a photovoltaic panel and then sealed with insulation in accordance with the subject invention;

FIG. 12 is a side view of the assembly shown in FIG. 11;

FIG. 13 is a schematic three-dimensional cross-sectional view of the assembly shown in FIG. 11;

FIG. 14 is a partial schematic cross-sectional view showing a portion of the assembly of FIG. 11;

FIG. 15 is a view showing an array of channels within a hermetically sealed housing in accordance with the subject invention;

FIG. 16 is a schematic view showing another arrangement of the channels within a hermetically sealed housing in accordance with the subject invention;

FIG. 17 is a schematic view showing examples of channels in a horizontal array in accordance with the subject invention;

FIG. 18 is a schematic view showing an example of channels in a vertical array in accordance with the subject invention; and

FIG. 19 is a block diagram showing the primary components associated with a supplemental solar energy collection system enabled hydrogen separation system in accordance with the subject invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

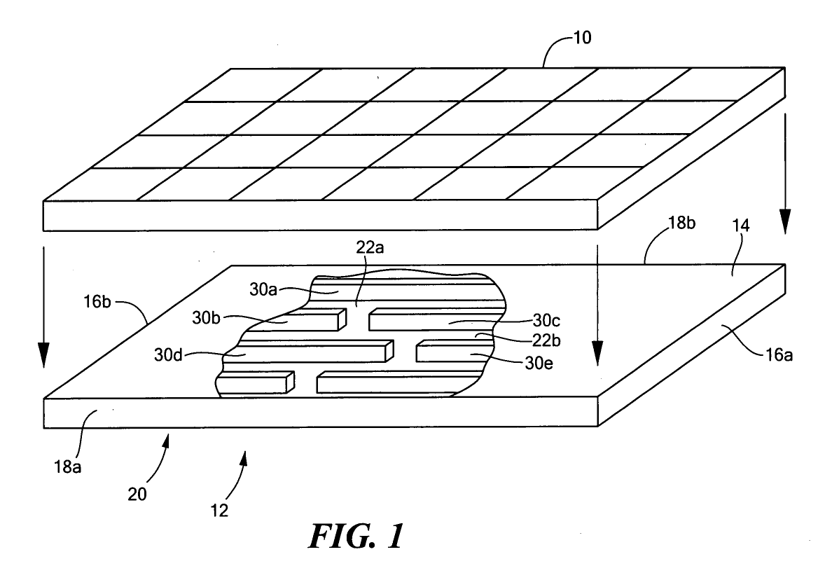

FIG. 1 shows photovoltaic panel 10 which converts incident solar radiation to electricity. Photovoltaic panel 10 is typically commercially available. FIG. 1 also shows supplemental solar energy collection housing 12 in accordance with the subject invention. Housing 12 includes top thermally conductive surface 14 (typically made of a thin sheet of aluminum) mated with the underside of photovoltaic panel 10 thus serving as a thermal collector.

In this preferred embodiment, housing 12 end walls 16a and 16b, side walls 18a and 18b, and bottom surface wall 20 define a hermetically sealed cavity with channels 22a, 22b, and the like therein carrying fluid in direct contact with the underside of top thermally conductive surface 14 itself mated with the underside of photovoltaic panel 10. In this example, these channels are defined by plates extending from the bottom surface 20 of housing 12 to the top surface 14 forming a gasket between the top and bottom of the housing. As shown, plates 30a, 30b, and 30c define channel 22a, while plates 30b, 30c, and 30d define channel 22b. Typically, insulation covers bottom surface 20 and may extend up around side walls 18a and 18b and end walls 16a and 16b.

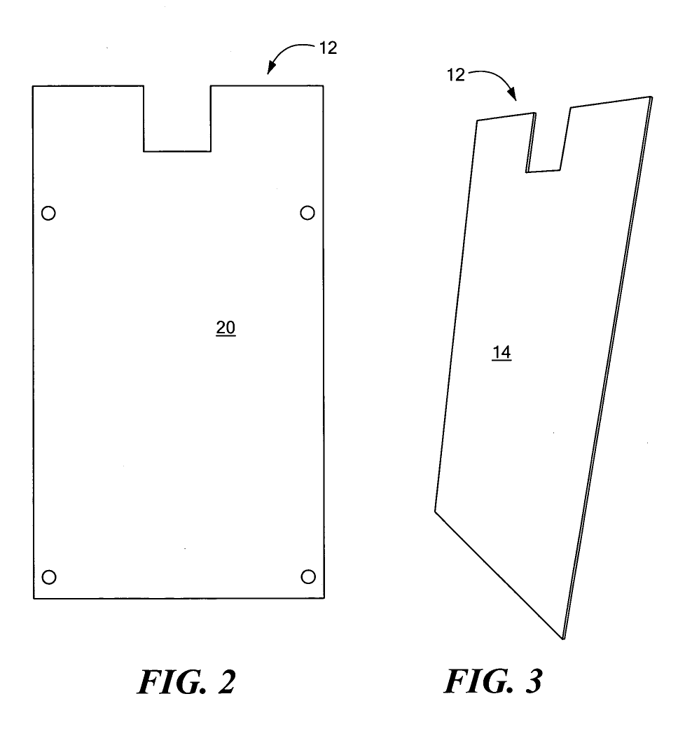

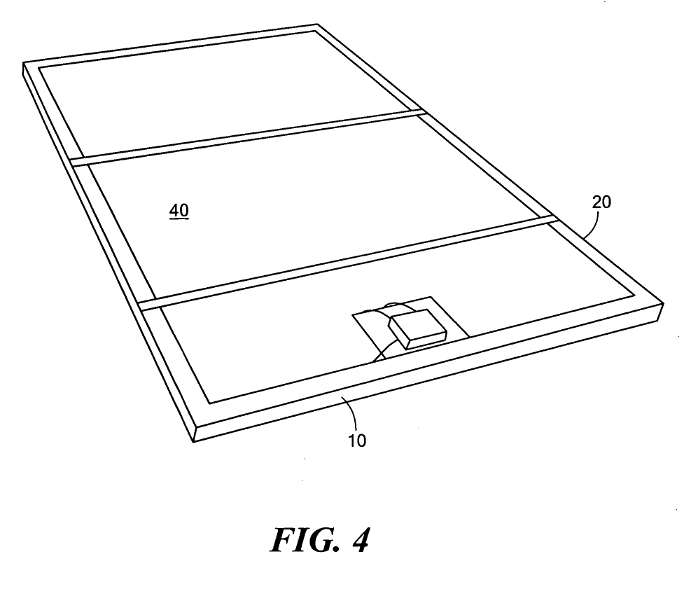

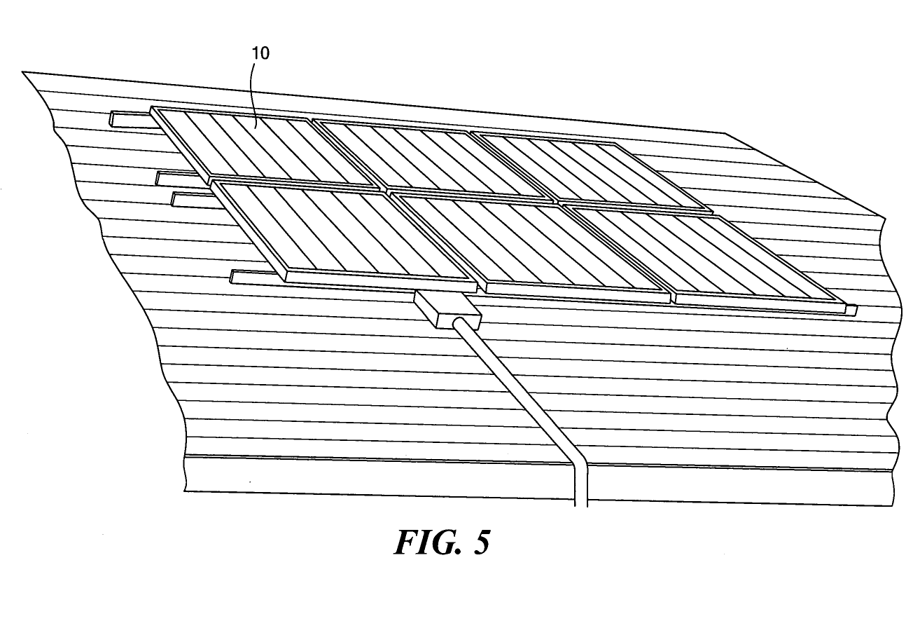

FIG. 2 also shows the bottom surface 20 of the hermetically sealed thermal collection housing while FIG. 3 shows top surface 14. FIG. 4 shows a housing 20 assembled onto photovoltaic panel 10 within its frame and the addition of insulation 40. FIG. 5 shows an example of photovoltaic panels mated with several thermal collection housings in accordance with the subject invention installed on the roof of a dwelling.

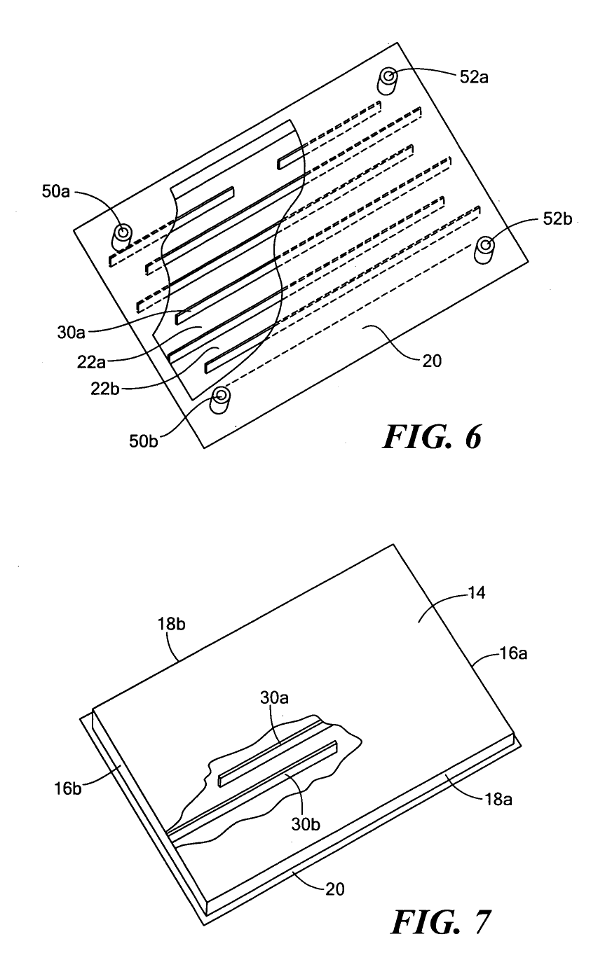

FIG. 6 shows bottom surface 20 with inlets 50a and 50b and outlets 52a and 52b for the fluid flowing within channels 22a, 22b, and the like defined by plate 30a and the like. As shown in FIG. 7, plate 30a extends from end wall 16a to the position spaced from end wall 16b while alternating plate 30b extends from end wall 16b to a position spaced from end wall 16a. The plates can also similarly alternate between extending from side wall 18a to a position spaced from side wall 18b and plates extending from side wall 18b to a position spaced from side wall 18a. Thermal grease can be spread across top thermally conductive surface 14 to provide a good thermal connection between top surface 14 and the bottom surface of the photovoltaic panel.

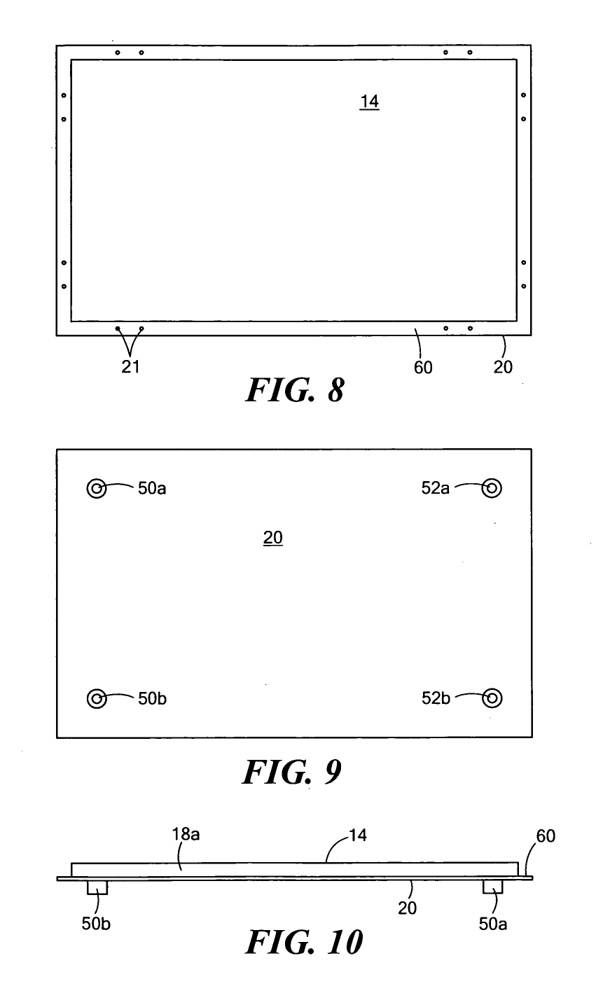

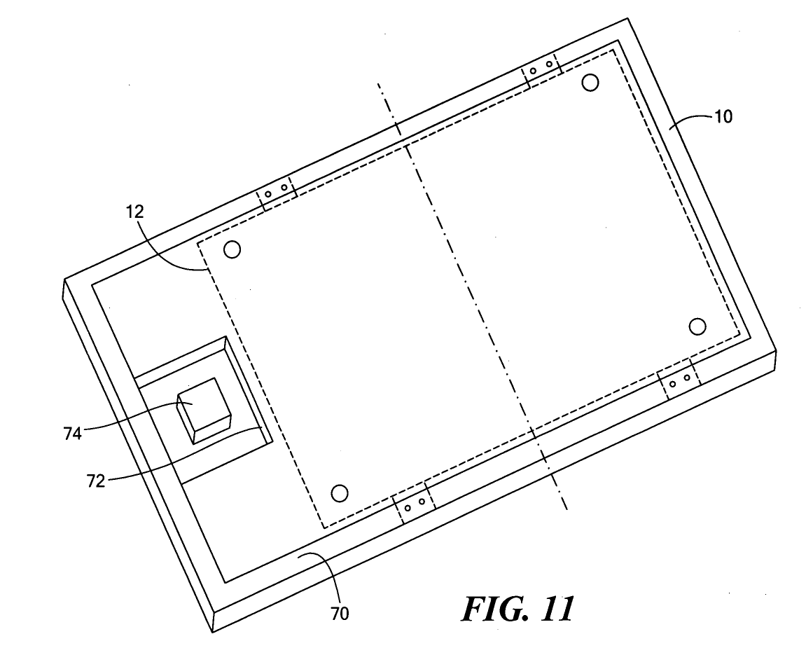

FIG. 8 shows top surface 14 and how bottom surface 20 may include peripheral flange portion 60 so that the bottom surface can be fastened too other structures without impacting the hermetic seal of the housing. FIG. 9 also shows bottom surface 20 and flow inlets 50a and 50b and outlets 52a and 52b. FIG. 10 shows side wall 18a. FIG. 11 shows a hermetically sealed collector housing in accordance with the subject invention mated with a photovoltaic panel including frame 70. The housing is shown in relief at 12 and it is covered with insulation 72 except in the area of the electrical junction box 74 of the photovoltaic panel.

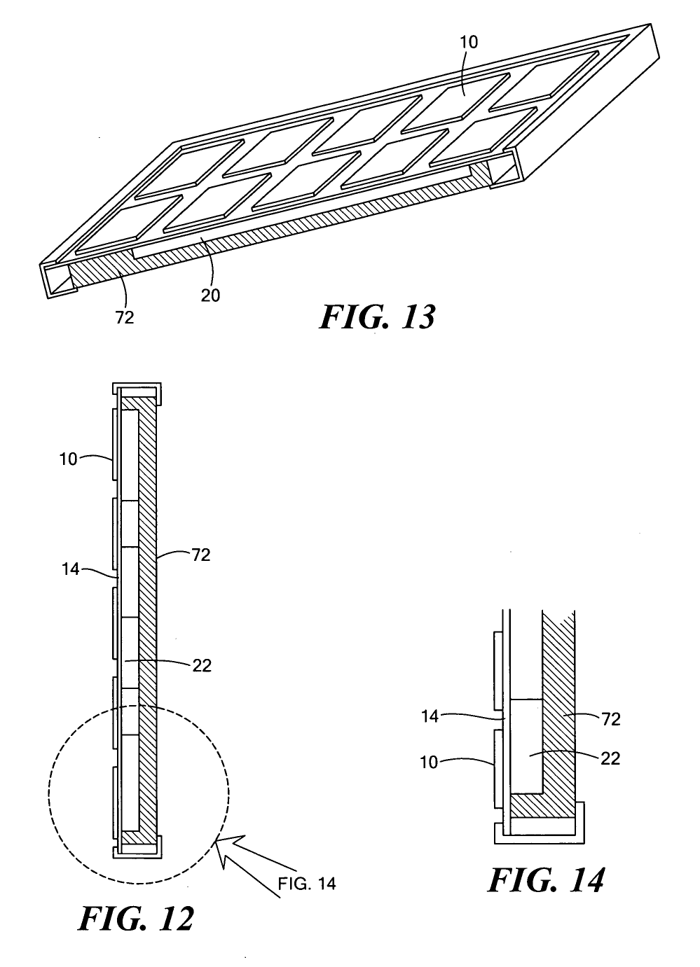

FIG. 12 shows a horizontal cross-section of SSEC 12 mated to photovoltaic panel 10. FIG. 13 shows a vertical cross-section of the SSEC mated to a photovoltaic panel. FIG. 14 shown in more detail the interface of the SSEC and PV panel showing they are touching but not attached at the panel interface.

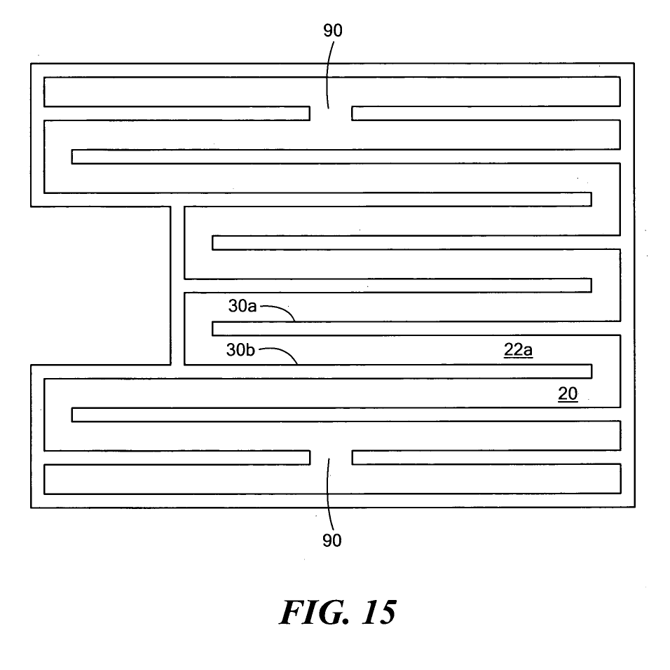

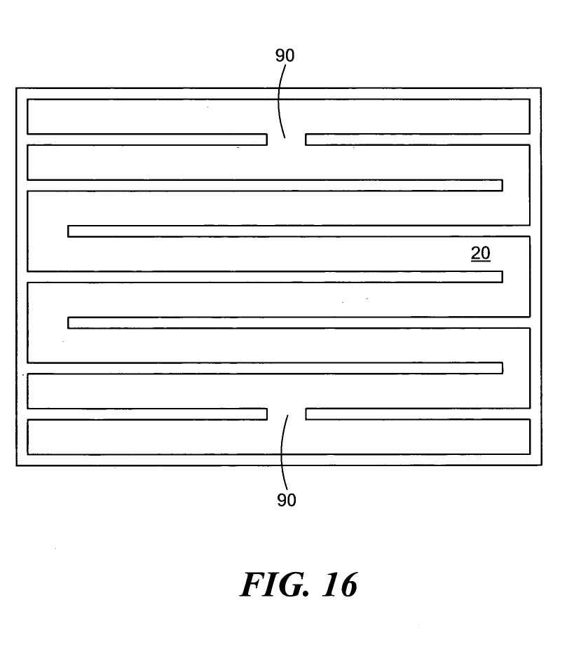

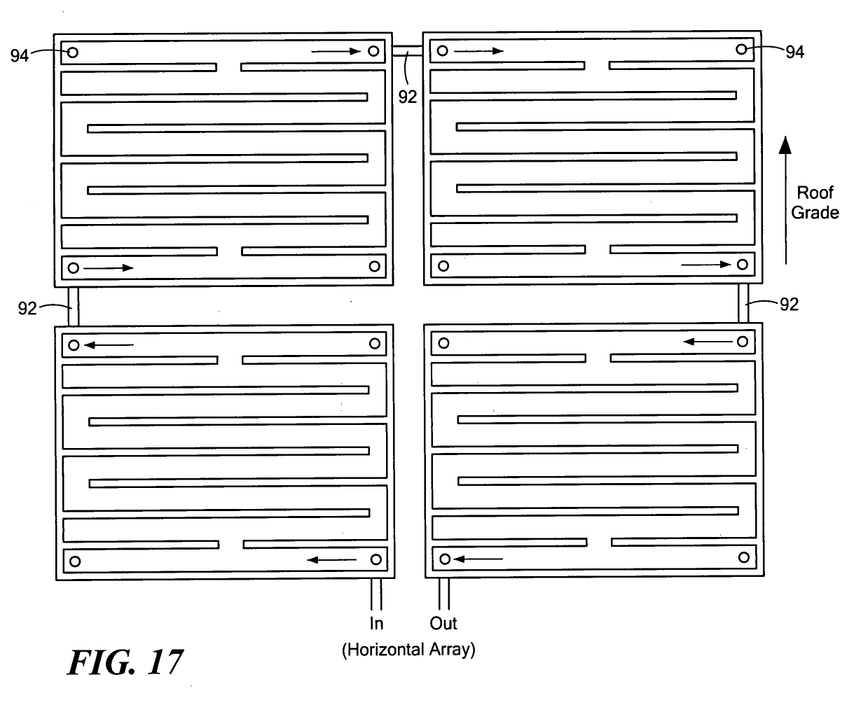

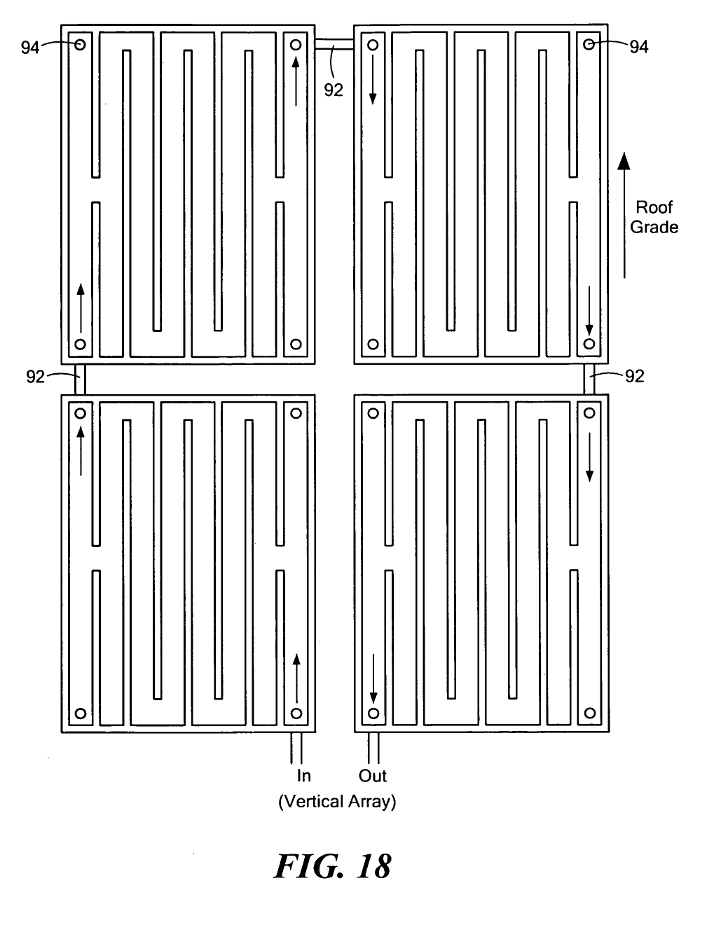

Another aspect of the invention is a unique flow pattern to allow high efficiency and easy installation/maintenance of the collector shown in, FIGS. 15 and 16. By splitting the inlet and outlet channel 90, versatility is provided to the collector without compromising efficiency. This allows external connections to be placed in all four corners of the SSEC. With the flow pattern and connections in all four corners it allows very short external connections 92 between collectors when installed in a grid pattern. This significantly reduces thermal losses and lowers cost. FIG. 17 shows a horizontal array configuration. Spare connections can be easily used for air/pressure relief valves or discharge valves 94. FIG. 18 shows a vertical array.

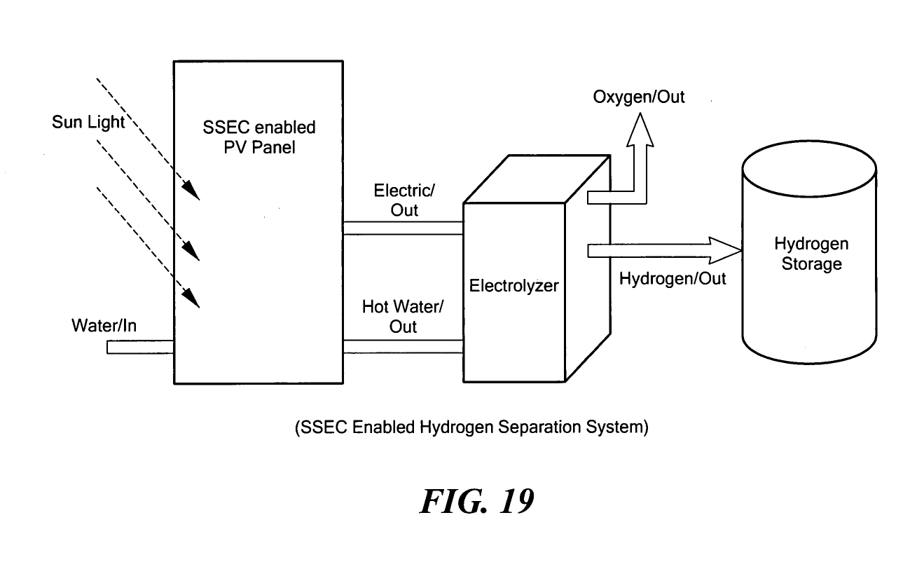

FIG. 19 shows a simple block diagram of how SSEC enabled PV panel could source electrolyses for efficient hydrogen generation and storage.

One objective of the subject invention is to maximize energy efficiency per radiant area while minimizing cost. U.S. Pat. No. 4,392,008 relates to an early attempt to achieve this goal. The Supplemental Solar Energy Collector (SSEC) of the subject invention introduces new innovations that further improve energy efficiency per radiant area. There are many manufactures of PV (photovoltaic) panels working to achieve low $/Watt. The SSEC does not typically include the PV panel. Instead, it is designed to be attached with commercially available PV arrays. Attachment can be part of the manufacturing process, during final installation, or added after initial installation. Rather than using piping, the SSEC includes an integrated housing. This housing maximizes surface area for thermal transport from the PV panel and thermal conductance to the transporting fluid. The housing top surface 14, FIG. 8 doubles as the thermal collector or plate. The SSEC also innovates a unique flow pattern through the housing allowing efficient thermal collection, reduction in thermal losses, and ease of installation/service. The result is a significant improvement in efficiency.

Table 1 shows experimental data taken using a SSEC prototype. Electrical energy is improved by approximately 0.4% per degree C of cooling. Useful thermal energy is collected by an increase of 195% in addition to PV alone when attaching the SSEC to the system. This increase energy without any change to collector area, thermal energy can be used for space heating, hot water, or improved efficiency of hydrogen separation.

TABLE 1

| Approx Irradiance | PV Electrical | SSEC thermal | Efficiency |
|---|---|---|---|
| Watts/m\hat{ }2 | Energy (Watts) | Energy (Watts)* | Improvement |
| 500 | 120 | 234 | 195% |
| 900 | 210 | 410 | 195% |

1 Watt = 3.14 BTU's

The preferred Supplemental Solar Energy collector comprises an integrated hermetically sealed housing/container made from a low cost, high thermal conductive material to mate with PV panels and extract thermal energy. An innovative flow pattern within the housing maximizes installation and service versatility, variable inlets/outlets to maximize installation versatility, insulation is provided to minimize thermal loss and to maximize energy collection and fasteners are used to ease installation with a variety of PV panels.

Designing the supplemental collector to be one integrated piece improves efficiencies. The housing surface mating with the PV panel is preferably planar and acts as a thermal collector and exchanger to the fluid circulating within. It is designed to maximize the surface area in contact with both the PV panel and circulating fluid. This maximizes the conversion of thermal energy and allows less expensive material to be used with only a small efficiency loss. Aluminum alloy is a choice of material though others can be used. For the Prototype, A5052 was chosen though production versions may use A357 to improve thermal performance. A thin layer of thermal grease can be applied between the PV panel and SSEC to improve thermal conductivity. Anticorrosive additives may be added to the fluid and an anticorrosive coating may be applied or plated on the housing.

The unique flow pattern maximizes energy collection while allowing versatile installation. Most thermal collectors restrict collector grid and inlet/outlet patterns and have a significant compromise in energy efficiency of increase in cost. The flow patterns described herein eliminate this concern and ease installation. In addition, the variable inlet/outlet patterns allow for easy implementation of air relief or discharge mechanisms. They also minimize the amount of connector tubing needed to connect multiple collectors together. This is also an improvement in array efficiency. Industrial hose or PVC are suggested as the means to inter-connect collectors, though many other connection techniques are available.

The insulation is designed to encapsulate the SSEC and match the PV panel design to appear as one unit. The purpose is to minimize heat losses across the large surface area of the collectors without impacting ease of installation. It is also designed to provide drainage away from PV electrical connections in the event of a leak and a measure of physical insulation from the PV junction box from any conductive components of the SSEC. Typical insulations are Polyisocyanurate or Polyurethane foam board. Polyisocyanurate insulation was used in the prototype.

The fasteners are designed for simple attachment of the SSEC to PV panels and roof mountings. Today there is not a standard size for PV panels so a variety of fastener sizes and housings are available.

In summary, the SSEC is designed to maximize the total energy efficiency of converting solar energy for useful means. Electricity can be used locally or connected to the grid. Thermal energy can be used for a variety of heating purposes today provided by electricity or fossil fuels. Also by combining both products one can improve electrolyzer efficiency in hydrogen separation.

One embodiment of the invention is for the housing to serve multiple purposes. It is designed to maximize surface area to absorb heat and transmit it to the transfer liquid. Mating surface 14 to the PV panel is shown in FIG. 7. A thermal grease can be applied to surface 14 to improve thermal conductivity. A bottom view of the housing is shown in FIG. 6 includes a interior view of wall's/fins 30a that create flow conduits 22 to efficiently transfer thermal energy. Multipurpose inlets/outlets 50 and 52 are designed for standard pipe thread connections. These allow easy connection to other collectors, pump, or storage. Care in connector selection is recommended so not to react with aluminum. A PVC connector is suggested though there are alternatives. The housing is hermetically sealed though each conduit is not fully isolated from each other allowing air to easily escape when filled or drained. FIG. 20 shows a possible design with lip 20, FIG. 7 extrudes from the housing either on the bottom or top to allow easy fastening without impacting the hermetic seal. Depending upon the PV panel design, fasteners are created to attach the SSEC to the PV panel. FIG. 8 shows where bolt holes 21 are designed into the lip for attachment. However depending upon the PV panel frame design, the lip or holes may or may not be necessary. The lip can also be designed into the top of the housing attachment during PV panel manufacture.

Another feature of the subject invention is a unique flow pattern to allow high efficiency and easy installation/maintenance of the collector, FIGS. 15-16. By splitting the inlet and outlet conduit as shown at 90, versatility is provided to the collector without compromising efficiency. This allows external connections to be placed in all four corners of the SSEC. With the flow pattern and connections in all four corners it allows very short external connections 92, FIG. 17 between collectors when installed in a grid pattern. This significantly reduces thermal losses and lowers cost. FIG. 11 shows a horizontal array configuration. Spare connections can be easily used for air/pressure relief valves or discharge valves 94. FIG. 18 shows a vertical array.

Insulation is designed to complete the mating with individual PV panels. Its purpose is to minimize thermal losses, provide electrical insulation from electrical components of the PV panel, and provide drainage channels away from PV electrical components. These channels provide protection from condensation and any potential leaks.

FIG. 19 shows how a SSEC enabled PV panel could source an electrolyzer for efficient hydrogen generation and storage.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments. Other embodiments will occur to those skilled in the art and are within the following claims.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

What is claimed is:

1. A supplemental solar energy collection system comprising:
a photovoltaic panel for converting incident radiation into electricity; and
a housing including:
a top thermally conductive surface mated with the photovoltaic panel and serving as a thermal collector, and
open channels behind the thermally conductive surface carrying fluid in contact with the top thermally conductive surface for removing heat from the photovoltaic panel.

2. The system of claim 1 in which the top thermally conductive surface is made of aluminum or another thermally conductive material.

3. The system of claim 1 further including thermal grease between the top thermally conductive surface and the photovoltaic panel.

4. The system of claim 1 further including an inlet into the housing and at least one outlet out of the housing for fluid in the channels.

5. The system of claim 1 in which the housing includes a bottom surface and first and second side walls and first and second end walls connecting the bottom surface to the top surface.

6. The system of claim 5 in which the channels are defined by gaskets between the bottom surface and the top surface.

7. The system of claim 6 in which alternating plates extend from the first end wall to a location spaced from the second end wall and then from the second end wall to a location spaced from the first end wall.

8. The system of claim 6 in which alternating plates extend from the first side wall to a location spaced from the second side wall and then from the second side wall to a location spaced from the first side wall.

9. The system of claim 1 in which the photovoltaic panel includes a frame, the housing resides within the frame, and insulation fills the frame over the housing.
